(19) United States
(12) Patent Application Publication
(10) Pub. No.: US 2023/0161995 A1
(43) Pub. Date: May 25, 2023

(54) DNA DATA STORAGE USING COMPOSITE FRAGMENTS

(71) Applicant: INTERNATIONAL BUSINESS MACHINES CORPORATION, Armonk, NY (US)

(72) Inventors: Koji Masuda, Chuo (JP); Toshiyuki Yamane, Setagaya (JP)

(21) Appl. No.: 17/533,720

(22) Filed: Nov. 23, 2021

(51) Int. Cl. G06N 3/00

(52) U.S. Cl. CPC G06N 3/002

(57) ABSTRACT

A computer-implemented method for storing information into a polynucleotide is provided including using multiple types of nucleotide fragments, wherein each of the nucleotide fragments has an individually different sequence of bases, configuring multiple composite fragments, wherein each of the composite fragments has a set of the nucleotide fragments with different ratios of the nucleotide fragments, and encoding, via an encoder, the information into the composite fragments.

### BACKGROUND

The present invention relates generally to DNA data storage, and more specifically, to methods and systems for DNA data storage by using composite fragments.

The digital universe could add some 175 zettabytes of data per year by 2025. That's 175 with 21 zeroes after it. That amount of information will require massive data centers and vast energy resources to maintain. Researchers are advocating DNA as a sustainable, stable replacement.

When most people think of DNA, they think of life, not computers. But DNA is itself a four-letter code for passing along information about an organism. DNA molecules are made from four types of bases, or nucleotides, each identified by a letter, that is, adenine (A), thymine (T), guanine (G) and cytosine (C). They are the basis of all DNA code, providing the instruction manual for building every living thing on earth.

A fairly well-understood technology, DNA synthesis has been widely used in medicine, pharmaceuticals and biofuel development, to name just a few applications. The technique organizes the bases into various arrangements indicated by specific sequences of A, C, G and T. These bases wrap in a twisted chain around each other, the familiar double helix, to form the molecule. The arrangement of these letters into sequences creates a code that tells an organism how to form.

The complete set of DNA molecules makes up the genome, that is, the blueprint of your body. By synthesizing DNA molecules, that is, making them from scratch, researchers have found they can specify, or write, long strings of the letters A, C, G and T and then read those sequences back. The process is analogous to how a computer stores binary information. From there, it was a short conceptual step to encoding a binary computer file into a molecule.

The method has been proven to work, but reading and writing the DNA-encoded files currently takes a long time. Appending a single base to DNA takes about one second. Writing an archive file at this rate could take decades, but research is developing faster methods, including massively parallel operations that write to many molecules at once.

ADS Codex indicates exactly how to translate the zeros and ones into sequences of four letter-combinations of A, C, G and T. The Codex also handles the decoding back into binary. DNA can be synthesized by several methods, and ADS Codex can accommodate them all.

Unfortunately, compared to traditional digital systems, the error rates while writing to molecular storage with DNA synthesis are very high. These errors arise from a different source than they do in the digital world, making them trickier to correct. On a digital hard disk, binary errors occur when a zero flips to a one, or vice versa. With DNA, the problems come from insertion and deletion errors. For instance, a user might be writing A-C-G-T, but sometimes one tries to write A, and nothing appears, so the sequence of letters shifts to the left, or it types AAA.

Normal error correction codes don't work well with that kind of problem, so ADS Codex adds error detection codes that validate the data. When the software converts the data back to binary, it tests to see that the codes match. If they don't, it removes or adds bases, that is, letters, until the verification succeeds. However, issues still persist.

Accordingly, a need exists for more efficient methodologies for DNA data storage.

### SUMMARY

In accordance with an embodiment, a computer-implemented method for storing information into a polynucleotide is provided. The computer-implemented method includes using multiple types of nucleotide fragments, wherein each of the nucleotide fragments has an individually different sequence of bases, configuring multiple composite fragments, wherein each of the composite fragments has a set of the nucleotide fragments with different ratios of the nucleotide fragments, and encoding, via an encoder, the information into the composite fragments.

In accordance with another embodiment, a computer-implemented method for interpreting information encoded in composite fragments is provided. The computer-implemented method includes analyzing polynucleotide sequences to determine a base sequence of each of the polynucleotide sequences, obtaining a ratio of sequences for each of the composite fragments corresponding to a position of each of the polynucleotide sequences, and decoding, via a decoder, the information based on the ratio of sequences for each of the composite fragments.

In accordance with yet another embodiment, a computer program product for storing information into a polynucleotide is provided. The computer program product includes a computer readable storage medium having program instructions embodied therewith, the program instructions executable by a computer to cause the computer to use multiple types of nucleotide fragments, wherein each of the nucleotide fragments has an individually different sequence of bases, configure multiple composite fragments, wherein each of the composite fragments has a set of the nucleotide fragments with different ratios of the nucleotide fragments, and encode, via an encoder, the information into the composite fragments.

In accordance with another embodiment, a computer program product for interpreting information encoded in composite fragments is provided. The computer program product includes a computer readable storage medium having program instructions embodied therewith, the program instructions executable by a computer to cause the computer to analyze polynucleotide sequences to determine a base sequence of each of the polynucleotide sequences, obtain a ratio of sequences for each of the composite fragments corresponding to a position of each of the polynucleotide sequences, and decode, via a decoder, the information based on the ratio of sequences for each of the composite fragments.

In accordance with yet another embodiment, a system for storing information into a polynucleotide is provided. The system includes an encoder to map digital information onto a set of composite fragments, a fragment assembly to biochemically concatenate the composite fragments such that a mixture ratio at a position in a sequence represents a state vector and to generate encoded DNA molecules, a sequencer to sample from a pool of the encoded DNA molecules at a predefined depth and count a read of each composite fragment, and a decoder to infer the mixture ratio from a frequency vector, find the nearest state vector, and map back to a binary representation.

In one preferred aspect, polynucleotide sequences are synthesized such that each of the nucleotide fragments of the composite fragments is incorporated in a same position of each of the polynucleotide sequences.

In another preferred aspect, the encoder maps bits of digital information onto a set of the composite fragments.

In yet another preferred aspect, state vectors for the composite fragments are given as cⱼ^{n,k}:=(σ₁/k, σ₂/k, . . . , σₙ/k), where σᵢ=0, 1, 2, . . . , k are a number of an ith fragment.

In yet another preferred aspect, a resolution is given as k=Σᵢ₌₁ⁿσᵢ.

In yet another preferred aspect, a complete set of the state vectors is given as Φ^{n,k}={cⱼ^{n,k}}, |Φ^{n,k}|=(ₙ₋₁^{k+n-1}).

In yet another preferred aspect, a subset of the complete set of state vectors used for coding is given as Σₘ={c₁^{n,k}, c₂^{n,k}, . . . , cₘ^{n,k}}.

In yet another preferred aspect, Σₘ is chosen to maximize an average distance between cⱼ^{n,k}.

In one preferred aspect, each of the composite fragments has a set of nucleotide fragments with different ratios.

In another preferred aspect, each of the nucleotide fragments has an individually different sequence of bases.

In yet another preferred aspect, each of the composite fragments are incorporated in a same position of each polynucleotide sequences.

In yet another preferred aspect, a sequencer samples from a pool of the encoded information at a predefined depth and counts a read of each of the composite fragments.

In yet another preferred aspect, the decoder finds nearest state vectors for the composite fragments.

In yet another preferred aspect, the decoder further maps the composite fragments into a binary representation.

The advantages of the present invention include at least that the number of states |Φ^{n,k}| can be significantly increased with n for a given value k. The composite fragment approach (n>4) can advantageously pack more information in a single synthesis cycle (e.g., bit/synthesis). Additionally, the ‘depth’ required to achieve a threshold accuracy (e.g., 90%) increases only with k, but not with n. The composite fragment approach is thus advantageous because higher bit/synthesis can be achieved without compromising the read-out accuracy and cost. The cost and time for synthesis advantageously improves by a factor proportional to a ratio of bit/synthesis achieved by the composite fragment (n>4) to that of the composite DNA (n=4). Moreover, improvement can be achieved by increasing n and by employing an efficient fragment assembly technique and microfluidics technique, estimating at least 3× and 2× improvement in speed and cost, respectively, compared to the composite DNA approach.

Other advantageous results relate to shallow sequencing, redundancy, and efficient read-out. For example, regarding shallow sequencing, to achieve a given bit/synthesis value, the composite fragment approach allows a lower value of k. A shallower sequence is sufficient to achieve a required accuracy, which reduces the readout cost significantly. Regarding redundancy, the large number of states obtained by the composite fragment allows redundant representation of the same data using a different set of fragments, providing flexibility and robustness for an implementation of unique error mitigation techniques. Regarding efficient readout, nanopore sequencers can be used to read out the composite fragments by recognizing different signal patterns of the fragments, as opposed to differentiating single nucleotides, to significantly increase the readout efficiency.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a block/flow diagram of an exemplary composite fragment, that is, a representation of a position in a DNA sequence that includes a mixture ratio of fragments, in accordance with an embodiment of the present invention;

FIG. 2 is a block/flow diagram of an exemplary encoding and decoding system and method using the composite fragment of FIG. 1, in accordance with an embodiment of the present invention;

FIG. 3 is a block/flow diagram of an exemplary method for encoding and decoding the composite fragment, in accordance with an embodiment of the present invention;

FIG. 4 is a block/flow diagram of an exemplary method for storing information into a polynucleotide, in accordance with an embodiment of the present invention;

FIG. 5 is a block/flow diagram of an exemplary method for interpreting information encoded in composite fragments, each of the composite fragments having a set of the nucleotide fragments with different ratios, in accordance with an embodiment of the present invention;

FIG. 6 is a diagram illustrating packing of more information in a single synthesis cycle, in accordance with an embodiment of the present invention;

FIG. 7 is a diagram illustrating achieving higher bit/synthesis without compromising read-out accuracy and cost, in accordance with an embodiment of the present invention;

FIG. 8 is a diagram illustrating cost and time synthesis improvement by a factor proportional to a ratio of bit/synthesis achieved by composite fragments, in accordance with an embodiment of the present invention;

FIG. 9 is a block/flow diagram of an exemplary processing system for employing composite fragments for DNA data storage, in accordance with an embodiment of the present invention;

FIG. 10 is a block/flow diagram of an exemplary cloud computing environment, in accordance with an embodiment of the present invention; and

FIG. 11 is a schematic diagram of exemplary abstraction model layers, in accordance with an embodiment of the present invention.

Throughout the drawings, same or similar reference numerals represent the same or similar elements.

### DETAILED DESCRIPTION

Embodiments in accordance with the present invention provide methods and devices for DNA data storage by using composite fragments.

All the world's data, all the digital photos and tweets, all the records of the global financial sector, all those satellite images, and glacial melting images, all the simulations underlying so much of modern science, and so much more, have to go somewhere. The “cloud” isn't a cloud at all. It is digital data centers in huge warehouses consuming vast amounts of electricity to store (and keep cool) trillions of millions of bytes. Costing billions of dollars to build, power and run, these data centers may struggle to remain viable as the need for data storage continues to grow exponentially. DNA shows great promise for satisfying the world's voracious appetite for data storage. The technology requires new tools and new ways of applying familiar ones. It won't be surprising if one day the world's most valuable archives find a new home in a poppy-seed-sized collection of molecules.

The process of DNA data storage combines DNA synthesis, DNA sequencing and an encoding and decoding algorithm to pack information into DNA more durably and at higher density than is possible in conventional media. That could be up to 17 exabytes per gram. As a result, DNA has garnered considerable interest as a medium of digital information storage because its density and durability are superior to those of existing silicon-based storage media. For example, DNA is at least 1000-fold more dense than most compact solid-state hard drives and at least 300-fold more durable than most stable magnetic tapes. DNA's four-letter nucleotide code offers a suitable coding environment that can be leveraged like the binary digital code used by computers and other electronic devices to represent any letter, digit, or other character. Despite these advantages, DNA has not yet become a widespread information storage medium because the cost of chemically synthesizing DNA is prohibitively high.

The exemplary embodiments of the present invention alleviate such issues by advantageously storing DNA using composite fragments.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

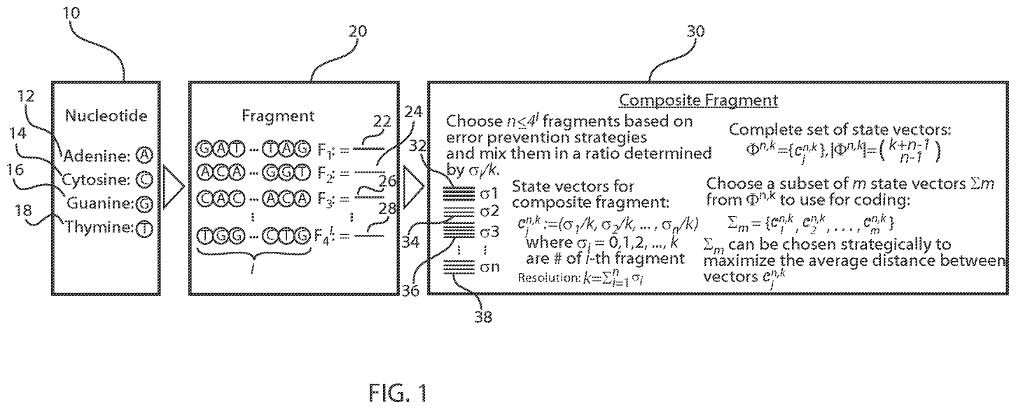

FIG. 1 is a block/flow diagram of an exemplary composite fragment, that is, a representation of a position in a DNA sequence that includes a mixture ratio of fragments, in accordance with an embodiment of the present invention.

The nucleotides 10 are assembled into nucleotide fragments 20.

The nucleotides 10 include adenine 12 (A), thymine 14 (T), guanine 16 (G) and cytosine 18 (C). They are the basis of all DNA code.

Fragments 20 are generated. For example, a first fragment 22, a second fragment 24, a third fragment 26, and a fourth fragment 28 are generated. Each fragment 22, 24, 26, 28 is a different sequence of the nucleotides 10.

Composite fragments 30 are then advantageously created.

For the composite fragments, n≤4¹ fragments are selected based on error prevention strategies and advantageously mixed into a ratio determined by σ₁/k.

The state vectors for the composite fragments are given as:

cⱼ^{n,k}:=(σ₁/k, σ₂/k, . . . , σₙ/k),

where σᵢ=0, 1, 2, . . . , k are a number of an ith fragment.

For example, state vectors 32 (σ₁), 34 (σ₂), 36 (σ₃), and 38 (σₙ) are generated.

The resolution is given as:

k=Σᵢ₌₁ⁿσᵢ.

The complete set of state vectors is given as:

Φ^{n,k}={cⱼ^{n,k}}, |Φ^{n,k}|=(ₙ₋₁^{k+n-1}).

A subset of m state vectors Σₘ is selected from Φ^{n,k} to use for coding:

Σₘ={c₁^{n,k}, c₂^{n,k}, . . . , cₘ^{n,k}}.

Σₘ can be strategically selected to maximize the average distance between vectors cⱼ^{n,k}.

Therefore, a composite fragment is a representation of a position in a DNA sequence that includes a mixture ratio of fragments.

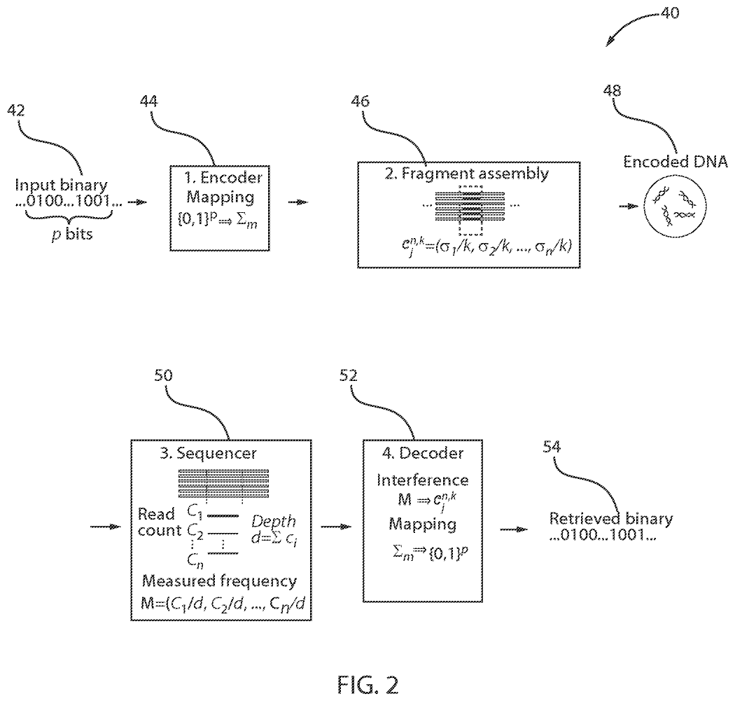

FIG. 2 is a block/flow diagram of an exemplary encoding and decoding system and method 40 using the composite fragment of FIG. 1, in accordance with an embodiment of the present invention.

An encoder 44 receives binary data 42. The binary data 42 can be referred to as p bits of digital information. The encoder 44 maps p bits of digital information onto a set of m composite fragments. The mapping can be represented as: {0,1}^{p}⇒Σₘ.

A fragment assembly 46 is then employed to advantageously biochemically concatenate fragments such that a mixture ratio at a position in the sequence represents a state vector cⱼ^{n,k}. In the fragment assembly 46, the state vector is given as: cⱼ^{n,k}:=(σ₁/k, σ₂/k, . . . , σₙ/k).

Encoded DNA 48 is then generated.

A sequencer 50 samples from a pool of the encoded DNA molecules 48 at a predefined ‘depth’ and counts the read of each composite fragment.

The decoder 52 advantageously infers the mixture ratio from the frequency vector [symbol] , finds the nearest cⱼ^{n,k}, and then maps back to a binary representation 54.

Therefore, the encoding scheme advantageously uses composite fragments to improve information density, synthesis speed, and cost-performance metrics. The composite fragments are a representation of a position in a DNA sequence that includes a mixture ratio of fragments. The exemplary embodiments thus use composite fragments, which increase the number of alphabets while keeping the composite resolution sufficiently low. This coding scheme of the exemplary embodiments advantageously reduces the cost and time for storing data in DNA by at least a factor of two compared to composite DNA. The exemplary method also offers additional advantages for error-correction.

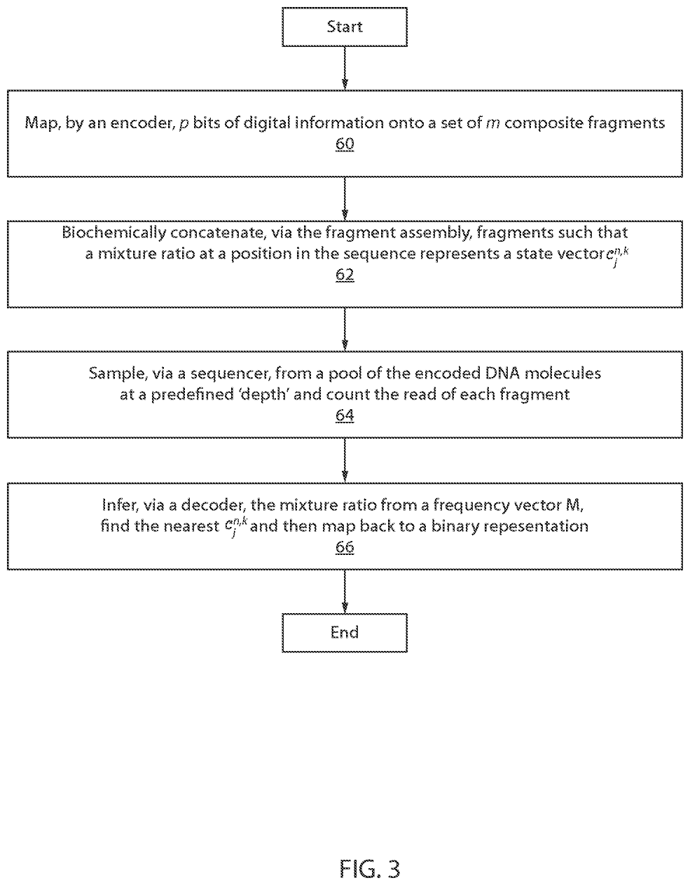

FIG. 3 is a block/flow diagram of an exemplary method for encoding and decoding the composite fragment, in accordance with an embodiment of the present invention.

At block 60, map, by an encoder, p bits of digital information onto a set of m composite fragments.

At block 62, biochemically concatenate, via the fragment assembly, fragments such that a mixture ratio at a position in the sequence represents a state vector cⱼ^{n,k}.

At block 64, sample, via a sequencer, from a pool of the encoded DNA molecules at a predefined ‘depth’ and count the read of each fragment.

At block 66, infer, via a decoder, the mixture ratio from a frequency vector [symbol] , find the nearest cⱼ^{n,k} and then map back to a binary representation.

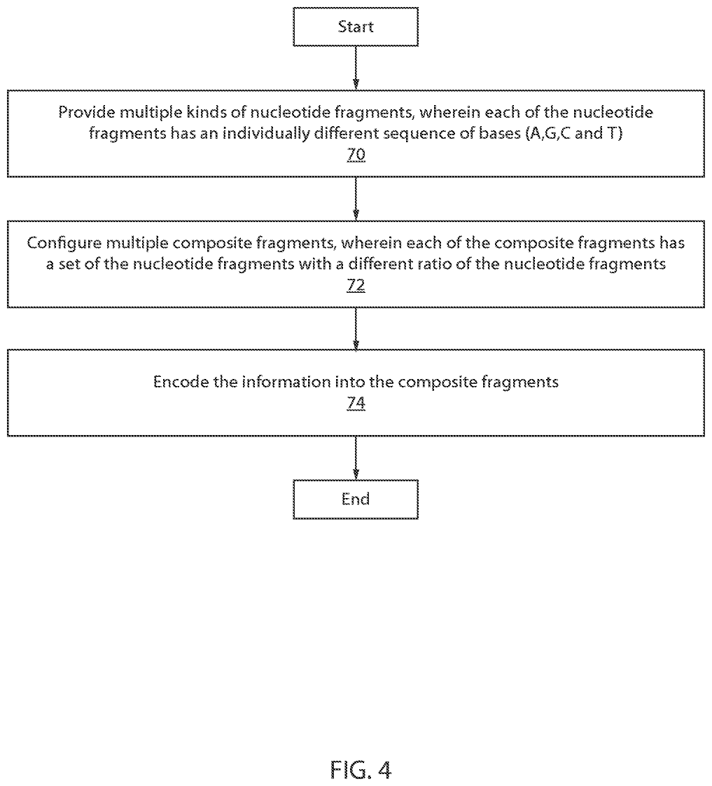

FIG. 4 is a block/flow diagram of an exemplary method for storing information into a polynucleotide, in accordance with an embodiment of the present invention.

At block 70, provide multiple kinds of nucleotide fragments, wherein each of the nucleotide fragments has an individually different sequence of bases (A, G, C and T).

At block 72, configure multiple composite fragments, wherein each of the composite fragments has a set of the nucleotide fragments with a different ratio of the nucleotide fragments.

At block 74, encode the information into the composite fragments.

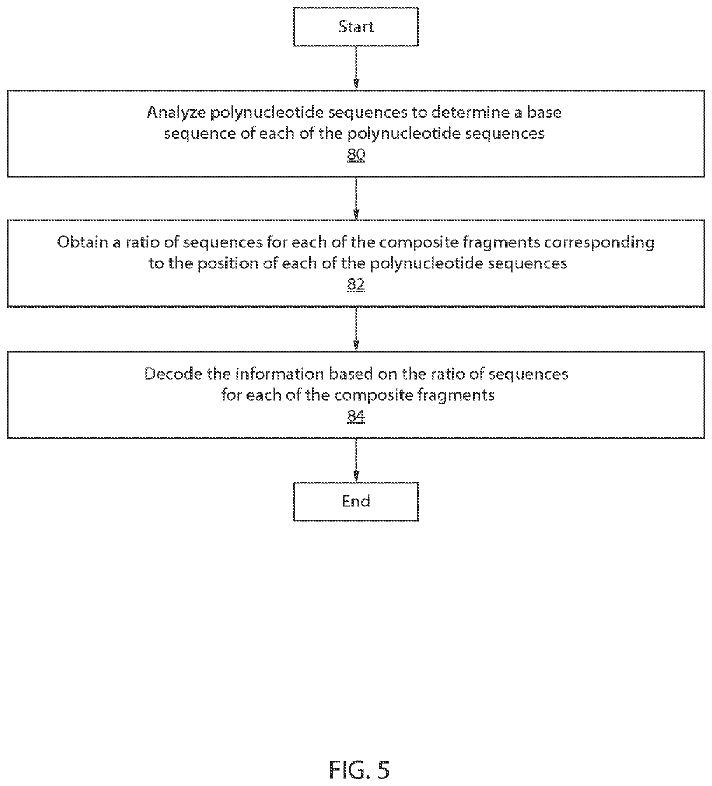

FIG. 5 is a block/flow diagram of an exemplary method for interpreting information encoded in composite fragments, each of the composite fragments having a set of the nucleotide fragments with different ratios, in accordance with an embodiment of the present invention.

At block 80, analyze polynucleotide sequences to determine a base sequence of each of the polynucleotide sequences.

At block 82, obtain a ratio of sequences for each of the composite fragments corresponding to the position of each of the polynucleotide sequences.

At block 84, decode the information based on the ratio of sequences for each of the composite fragments.

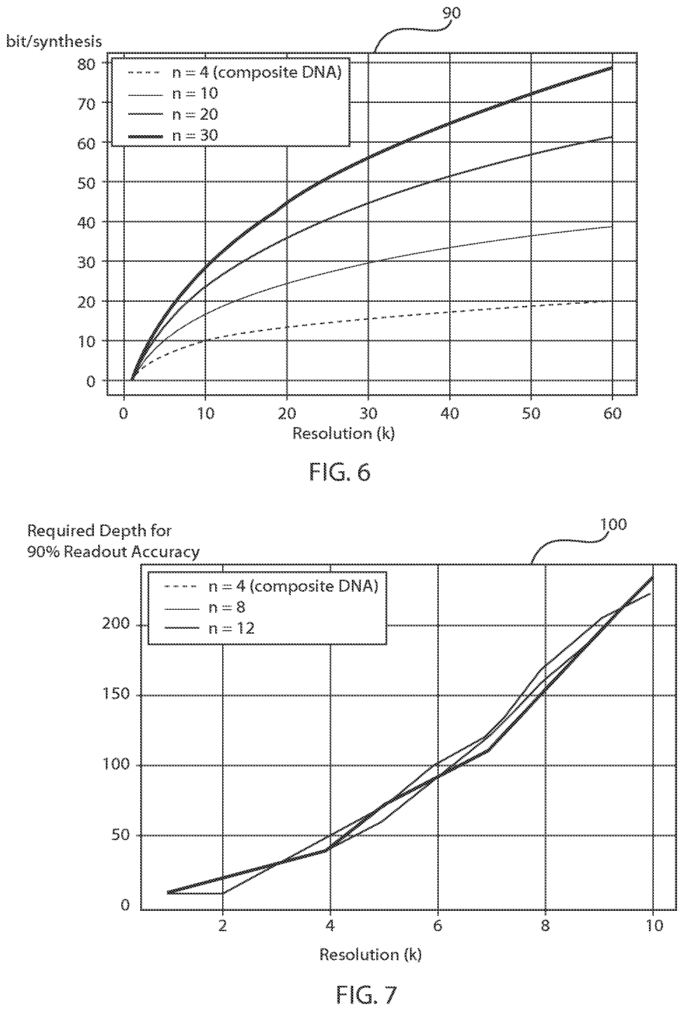

FIG. 6 is a diagram illustrating the packing of more information in a single synthesis cycle, in accordance with an embodiment of the present invention.

Diagram 90 illustrates resolution (k) on the x-axis and bit/synthesis on the y-axis. The higher the n, the larger the bit/synthesis.

The advantages of the present invention include at least that the number of states |Φ^{n,k}| can be significantly increased with n for a given value k. The composite fragment approach (n>4) can advantageously pack more information in a single synthesis cycle (e.g., bit/synthesis).

FIG. 7 is a diagram illustrating achieving higher bit/synthesis without compromising read-out accuracy and cost, in accordance with an embodiment of the present invention.

Diagram 100 illustrates resolution (k) on the x-axis and required ‘depth’ for 90% accuracy read-out on the y-axis.

Additionally, further advantages include that the ‘depth’ required to achieve a threshold accuracy (e.g., 90%) increases only with k, but not with n. The composite fragment approach is thus advantageous because higher bit/synthesis can be achieved without compromising the read-out accuracy and cost.

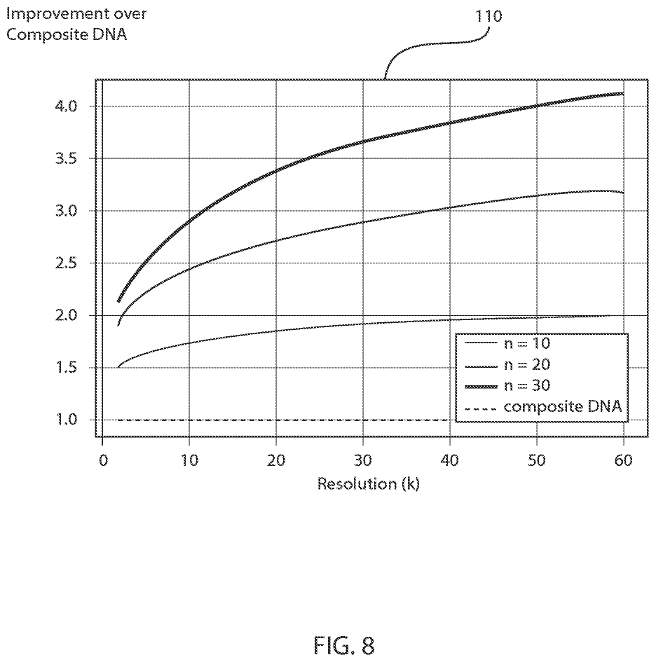

FIG. 8 is a diagram illustrating cost and time synthesis improvement by a factor proportional to a ratio of bit/synthesis achieved by composite fragments, in accordance with an embodiment of the present invention.

Diagram 110 illustrates resolution (k) on the x-axis and improvement over composite DNA on the y-axis. The higher the n, the more improvement over the composite DNA.

The cost and time for synthesis advantageously improves by a factor proportional to a ratio of bit/synthesis achieved by the composite fragment (n>4) to that of the composite DNA (n=4). Moreover, improvement can be achieved by increasing n and by employing an efficient fragment assembly technique and microfluidics technique, estimating at least 3× and 2× improvement in speed and cost, respectively, compared to the composite DNA approach.

In summary, with respect to FIGS. 6-8, other advantageous results relate to shallow sequencing, redundancy, and efficient read-out. For example, regarding shallow sequencing, to achieve a given bit/synthesis value, the composite fragment approach allows a lower value of k. A shallower sequence is sufficient to achieve a required accuracy, which reduces the readout cost significantly. Regarding redundancy, the large number of states obtained by the composite fragment allows redundant representation of the same data using a different set of fragments, providing flexibility and robustness for an implementation of unique error mitigation techniques. Regarding efficient readout, nanopore sequencers can be used to read out the composite fragments by recognizing different signal patterns of the fragments, as opposed to differentiating single nucleotides, to significantly increase the readout efficiency.

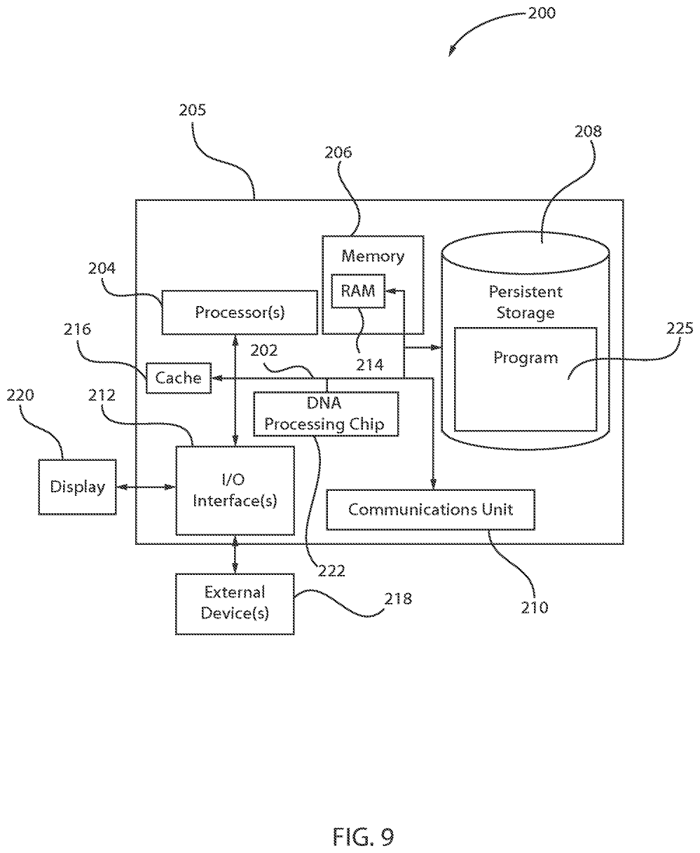

FIG. 9 is a block/flow diagram of an exemplary processing system for employing composite fragments for DNA data storage, in accordance with an embodiment of the present invention.

FIG. 9 depicts a block diagram of components of system 200, which includes computing device 205. It should be appreciated that FIG. 9 provides only an illustration of one implementation and does not imply any limitations with regard to the environments in which different embodiments can be implemented. Many modifications to the depicted environment can be made.

Computing device 205 includes communications fabric 202, which provides communications between computer processor(s) 204, memory 206, persistent storage 208, communications unit 210, and input/output (I/O) interface(s) 212. Communications fabric 202 can be implemented with any architecture designed for passing data and/or control information between processors (such as microprocessors, communications and network processors, etc.), system memory, peripheral devices, and any other hardware components within a system. For example, communications fabric 202 can be implemented with one or more buses.

Memory 206, cache memory 216, and persistent storage 208 are computer readable storage media. In this embodiment, memory 206 includes random access memory (RAM) 214. In another embodiment, the memory 206 can be flash memory. In general, memory 206 can include any suitable volatile or non-volatile computer readable storage media.

In some embodiments of the present invention, program 225 is included and operated by DNA processing chip 222 as a component of computing device 205. In other embodiments, program 225 is stored in persistent storage 208 for execution by DNA processing chip 222 (to implement DNA data storage by using composite fragments) in conjunction with one or more of the respective computer processors 204 via one or more memories of memory 206. In this embodiment, persistent storage 208 includes a magnetic hard disk drive. Alternatively, or in addition to a magnetic hard disk drive, persistent storage 208 can include a solid state hard drive, a semiconductor storage device, read-only memory (ROM), erasable programmable read-only memory (EPROM), flash memory, or any other computer readable storage media that is capable of storing program instructions or digital information.

The media used by persistent storage 208 can also be removable. For example, a removable hard drive can be used for persistent storage 208. Other examples include optical and magnetic disks, thumb drives, and smart cards that are inserted into a drive for transfer onto another computer readable storage medium that is also part of persistent storage 208.

Communications unit 210, in these examples, provides for communications with other data processing systems or devices, including resources of distributed data processing environment. In these examples, communications unit 210 includes one or more network interface cards. Communications unit 210 can provide communications through the use of either or both physical and wireless communications links. Deep learning program 225 can be downloaded to persistent storage 208 through communications unit 210.

I/O interface(s) 212 allows for input and output of data with other devices that can be connected to computing system 200. For example, I/O interface 212 can provide a connection to external devices 218 such as a keyboard, keypad, a touch screen, and/or some other suitable input device. External devices 218 can also include portable computer readable storage media such as, for example, thumb drives, portable optical or magnetic disks, and memory cards.

Display 220 provides a mechanism to display data to a user and can be, for example, a computer monitor.

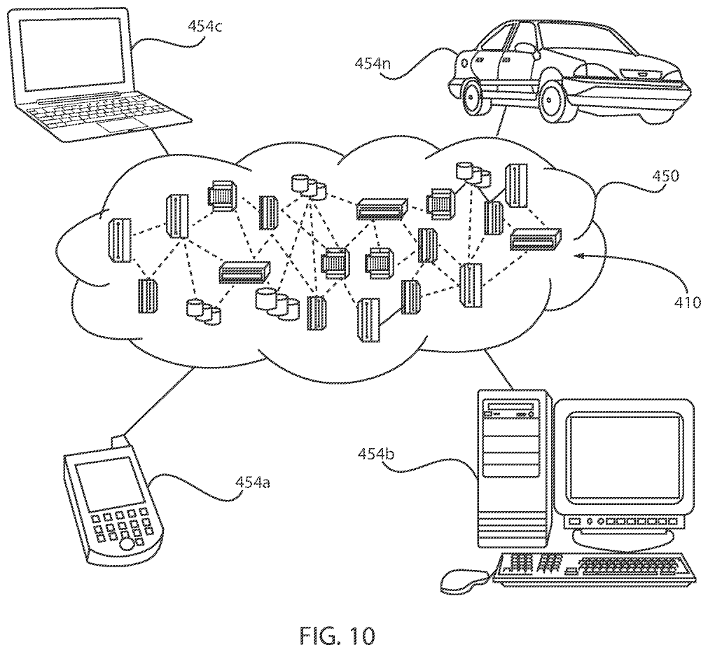

FIG. 10 is a block/flow diagram of an exemplary cloud computing environment, in accordance with an embodiment of the present invention.

It is to be understood that although this invention includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model can include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but can be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It can be managed by the organization or a third party and can exist on-premises or off-premises.

Community cloud: the cloud infrastructure is shared by several organizations and supports a specific community that has shared concerns (e.g., mission, security requirements, policy, and compliance considerations). It can be managed by the organizations or a third party and can exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

Referring now to FIG. 10, illustrative cloud computing environment 450 is depicted for enabling use cases of the present invention. As shown, cloud computing environment 450 includes one or more cloud computing nodes 410 with which local computing devices used by cloud consumers, such as, for example, personal digital assistant (PDA) or cellular telephone 454A, desktop computer 454B, laptop computer 454C, and/or automobile computer system 454N can communicate. Nodes 410 can communicate with one another. They can be grouped (not shown) physically or virtually, in one or more networks, such as Private, Community, Public, or Hybrid clouds as described hereinabove, or a combination thereof. This allows cloud computing environment 450 to offer infrastructure, platforms and/or software as services for which a cloud consumer does not need to maintain resources on a local computing device. It is understood that the types of computing devices 454A-N shown in FIG. 10 are intended to be illustrative only and that computing nodes 410 and cloud computing environment 450 can communicate with any type of computerized device over any type of network and/or network addressable connection (e.g., using a web browser).

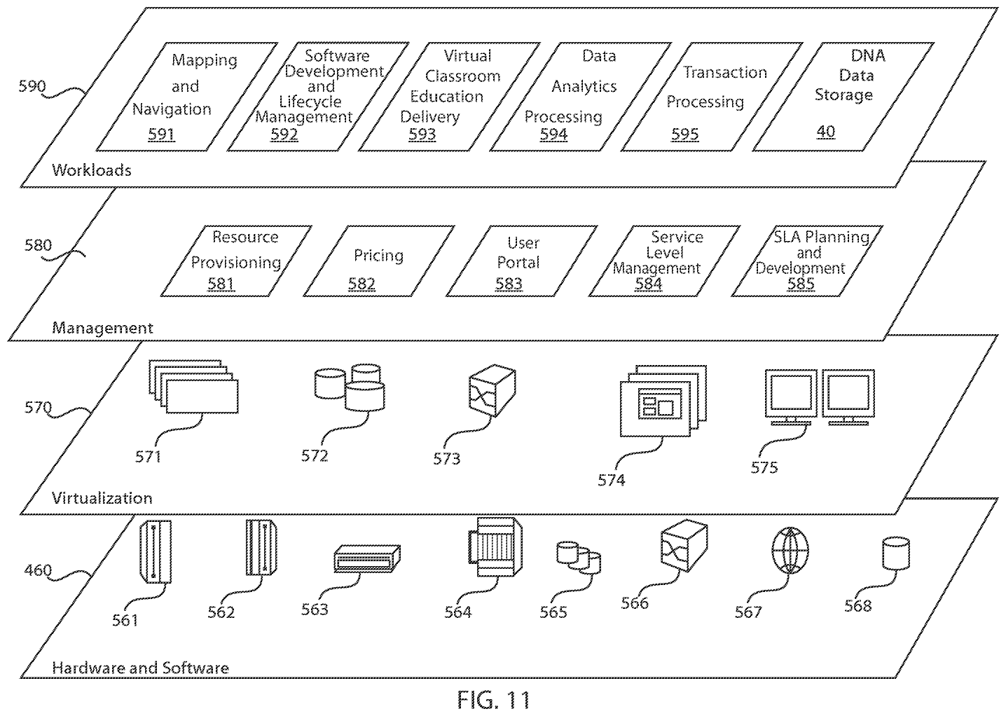

FIG. 11 is a schematic diagram of exemplary abstraction model layers, in accordance with an embodiment of the present invention. It should be understood in advance that the components, layers, and functions shown in FIG. 11 are intended to be illustrative only and embodiments of the invention are not limited thereto. As depicted, the following layers and corresponding functions are provided:

Hardware and software layer 560 includes hardware and software components. Examples of hardware components include: mainframes 561; RISC (Reduced Instruction Set Computer) architecture based servers 562; servers 563; blade servers 564; storage devices 565; and networks and networking components 566. In some embodiments, software components include network application server software 567 and database software 568.

Virtualization layer 570 provides an abstraction layer from which the following examples of virtual entities can be provided: virtual servers 571; virtual storage 572; virtual networks 573, including virtual private networks; virtual applications and operating systems 574; and virtual clients 575.

In one example, management layer 580 can provide the functions described below. Resource provisioning 581 provides dynamic procurement of computing resources and other resources that are utilized to perform tasks within the cloud computing environment. Metering and Pricing 582 provide cost tracking as resources are utilized within the cloud computing environment, and billing or invoicing for consumption of these resources. In one example, these resources can include application software licenses. Security provides identity verification for cloud consumers and tasks, as well as protection for data and other resources. User portal 583 provides access to the cloud computing environment for consumers and system administrators. Service level management 584 provides cloud computing resource allocation and management such that required service levels are met. Service Level Agreement (SLA) planning and fulfillment 585 provide pre-arrangement for, and procurement of, cloud computing resources for which a future requirement is anticipated in accordance with an SLA.

Workloads layer 590 provides examples of functionality for which the cloud computing environment can be utilized. Examples of workloads and functions which can be provided from this layer include: mapping and navigation 541; software development and lifecycle management 592; virtual classroom education delivery 593; data analytics processing 594; transaction processing 595; and DNA data storage 40.

The present invention can be a system, a method, and/or a computer program product. The computer program product can include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory, a read-only memory, an erasable programmable read-only memory (EPROM or Flash memory), a static random access memory, a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can include copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention can be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions can be provided to at least one processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks or modules. These computer readable program instructions can also be stored in a computer readable storage medium that can direct a computer, a programmable data processing apparatus, and/or other devices to function in a particular manner, such that the computer readable storage medium having instructions stored therein includes an article of manufacture including instructions which implement aspects of the function/act specified in the flowchart and/or block diagram block or blocks or modules.

The computer readable program instructions can also be loaded onto a computer, other programmable data processing apparatus, or other device to cause a series of operational blocks/steps to be performed on the computer, other programmable apparatus or other device to produce a computer implemented process, such that the instructions which execute on the computer, other programmable apparatus, or other device implement the functions/acts specified in the flowchart and/or block diagram block or blocks or modules.

The flowchart and block diagrams in the Figures illustrate the architecture, functionality, and operation of possible implementations of systems, methods, and computer program products according to various embodiments of the present invention. In this regard, each block in the flowchart or block diagrams can represent a module, segment, or portion of instructions, which includes one or more executable instructions for implementing the specified logical function(s). In some alternative implementations, the functions noted in the blocks can occur out of the order noted in the figures. For example, two blocks shown in succession can, in fact, be executed substantially concurrently, or the blocks can sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

Having described preferred embodiments of methods and systems for DNA data storage by using composite fragments (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A computer-implemented method for storing information into a polynucleotide, the computer-implemented method comprising:
using multiple types of nucleotide fragments, wherein each of the nucleotide fragments has an individually different sequence of bases;
configuring multiple composite fragments, wherein each of the composite fragments has a set of the nucleotide fragments with different ratios of the nucleotide fragments; and
encoding, via an encoder, the information into the composite fragments.

2. The computer-implemented method of claim 1, further comprising synthesizing polynucleotide sequences, wherein each of the nucleotide fragments of the composite fragments is incorporated in a same position of each of the polynucleotide sequences.

3. The computer-implemented method of claim 1, wherein the encoder maps bits of digital information onto a set of the composite fragments.

4. The computer-implemented method of claim 1, wherein state vectors for the composite fragments are given as:
cⱼ^{n,k}:=(σ₁/k, σ₂/k, . . . , σₙ/k),
where σᵢ=0, 1, 2, . . . , k are a number of an ith fragment.

5. The computer-implemented method of claim 4, wherein a resolution is given as:
k=Σᵢ₌₁ⁿσᵢ.

6. The computer-implemented method of claim 5, wherein a complete set of the state vectors is given as:
Φ^{n,k}={cⱼ^{n,k}}, |Φ^{n,k}|=(ₙ₋₁^{k+n-1}).

7. The computer-implemented method of claim 6, wherein a subset of the complete set of state vectors used for coding is given as:
Σₘ={c₁^{n,k}, c₂^{n,k}, . . . , cₘ^{n,k}}.

8. The computer-implemented method of claim 7, wherein Σₘ is chosen to maximize an average distance between cⱼ^{n,k}.

9. A computer-implemented method for interpreting information encoded in composite fragments, the computer-implemented method comprising:
analyzing polynucleotide sequences to determine a base sequence of each of the polynucleotide sequences;
obtaining a ratio of sequences for each of the composite fragments corresponding to a position of each of the polynucleotide sequences; and
decoding, via a decoder, the information based on the ratio of sequences for each of the composite fragments.

10. The computer-implemented method of claim 9, wherein each of the composite fragments has a set of nucleotide fragments with different ratios.

11. The computer-implemented method of claim 10, wherein each of the nucleotide fragments has an individually different sequence of bases.

12. The computer-implemented method of claim 11, wherein each of the composite fragments are incorporated in a same position of each polynucleotide sequences.

13. The computer-implemented method of claim 9, wherein a sequencer samples from a pool of the encoded information at a predefined depth and counts a read of each of the composite fragments.

14. The computer-implemented method of claim 9, wherein the decoder finds nearest state vectors for the composite fragments.

15. The computer-implemented method of claim 14, wherein the decoder further maps the composite fragments into a binary representation.

16. A computer program product for storing information into a polynucleotide, the computer program product comprising a computer readable storage medium having program instructions embodied therewith, the program instructions executable by a computer to cause the computer to:
use multiple types of nucleotide fragments, wherein each of the nucleotide fragments has an individually different sequence of bases;
configure multiple composite fragments, wherein each of the composite fragments has a set of the nucleotide fragments with different ratios of the nucleotide fragments; and
encode, via an encoder, the information into the composite fragments.

17. The computer program product of claim 16, wherein the polynucleotide sequences are synthesized, and wherein each of the nucleotide fragments of the composite fragments is incorporated in a same position of each of the polynucleotide sequences.

18. The computer program product of claim 16, wherein the encoder maps bits of digital information onto a set of the composite fragments.

19. The computer program product of claim 16, wherein state vectors for the composite fragments are given as:
cⱼ^{n,k}:=(σ₁/k, σ₂/k, . . . , σₙ/k),
where σᵢ=0, 1, 2, . . . , k are a number of an ith fragment.

20. The computer program product of claim 19, wherein a complete set of the state vectors is given as:
Φ^{n,k}={cⱼ^{n,k}}, |Φ^{n,k}|=(ₙ₋₁^{k+n-1}).

21. The computer program product of claim 20, wherein a subset of the complete set of state vectors used for coding is given as:
Σₘ={c₁^{n,k}, c₂^{n,k}, . . . , cₘ^{n,k}}.

22. A computer program product for interpreting information encoded in composite fragments, the computer program product comprising a computer readable storage medium having program instructions embodied therewith, the program instructions executable by a computer to cause the computer to:
analyze polynucleotide sequences to determine a base sequence of each of the polynucleotide sequences;
obtain a ratio of sequences for each of the composite fragments corresponding to a position of each of the polynucleotide sequences; and
decode, via a decoder, the information based on the ratio of sequences for each of the composite fragments.

23. The computer program product of claim 22, wherein each of the composite fragments has a set of nucleotide fragments with different ratios, wherein each of the nucleotide fragments has an individually different sequence of bases, and wherein each of the composite fragments are incorporated in a same position of each polynucleotide sequences.

24. A system for storing information into a polynucleotide, the system comprising:
an encoder to map digital information onto a set of composite fragments;
a fragment assembly to biochemically concatenate the composite fragments such that a mixture ratio at a position in a sequence represents a state vector and to generate encoded DNA molecules;
a sequencer to sample from a pool of the encoded DNA molecules at a predefined depth and count a read of each composite fragment; and
a decoder to infer the mixture ratio from a frequency vector, find the nearest state vector, and map back to a binary representation.

25. The system of claim 24, wherein a state vector for the composite fragments is given as:
cⱼ^{n,k}:=(σ₁/k, σ₂/k, . . . , σₙ/k),
where σᵢ=0, 1, 2, . . . , k are a number of an ith fragment.
